(19) United States
(12) Patent Application Publication
(10) Pub. No.: US 2017/0354999 A1
(43) Pub. Date: Dec. 14, 2017

(54) METHOD FOR FORMING SUPER WATER-REPELLENT AND SUPER OIL-REPELLENT SURFACE, AND OBJECT MANUFACTURED THEREBY

(71) Applicant: NUOSGUI, SEOUL (KR)

(72) Inventor: Hyun Bae SEO, Gyeonggi-do (KR)

(73) Assignee: NUOSGUI, SEOUL (KR)

(21) Appl. No.: 15/540,058

(22) PCT Filed: Apr. 6, 2016
(86) PCT No.: PCT/KR2016/003576

§ 371 Date: Jun. 27, 2017

(30) Foreign Application Priority Data
Apr. 8, 2015 (KR) 10-2015-0049805

(51) Int. Cl. B08B 17/06; C23C 16/40; C08F 120/24; C23C 16/02

(52) U.S. Cl. CPC B08B 17/06; C23C 16/0245; C23C 16/402; C08F 120/24; C08J 2333/08; C08J 2333/10

(57) ABSTRACT

The present invention relates to a technology of solving an issue where screens are contaminated with pollution caused by fingerprints, cosmetics, etc. on covers or windows of mobile devices such as smartphones, tablets, etc. and other user contact devices, thereby maintaining the excellent surface hardness properties of existing covers or windows and preventing deterioration of surface properties (antifouling properties) even when used long-term. The method for forming a surface having super water-repellent and super oil-repellent properties comprises the steps of: etching a surface of a target on which a surface with super water-repellent and super oil-repellent properties will be formed, to thereby form a surface structure in which convex parts ( [symbol] ) and concave parts ( [symbol] ) are continuously formed; and performing a conformal coating for coating a fluorine-based material on the surface structure which is etched on the surface of the target, wherein all configuration walls of the convex parts and all configuration walls of the concave parts are coated at a uniform thickness.

### CROSS REFERENCE TO RELATED APPLICATIONS

This application is a National Stage of International Application No. PCT/KR2016/003576 filed Apr. 6, 2016, claiming priority based on Korean Patent Application No. 10-2015-0049805 filed Apr. 8, 2015, the contents of all of which are incorporated herein by reference in their entirety.

### BACKGROUND OF THE INVENTION

### 1. Field of the Invention

The present invention relates to a technology which solves problems associated with the contamination of covers or windows of mobile devices, such as smartphones or tablet PCs, and other devices with which the user comes into contact, with fingerprints, cosmetics or the like, so as to enable the cover or windows to maintain excellent surface hardness characteristics and prevent deterioration in the surface properties (e.g., antifouling properties) of the covers or windows even when they are used for a long time.

### 2. Description of the Prior Art

Generally, the surface of various devices or articles, which is exposed to an environment or with which the user comes into contact, is treated into water-repellent or oil-repellent surface feature. In recent years, due to wide diffusion of touch-type interface devices (e.g., touch-type LCDs, smartphone displays, electronic door locks, etc.), the need for such water-repellent or oil-repellent surfaces has increased, and the requirements for the performance of such surfaces have become more strict. In addition to such touch-type interface devices, the requirements for water-repellent or oil-repellent treatment for preventing contamination of surfaces have become stricter for the surfaces of devices, such as refrigerators, cooking utensils and other domestic electronic devices, or parts thereof (refrigerator handles, smartphone covers, etc.), which are exposed to water and oil components.

In a conventional art, surface contamination has generally been prevented by lowering the surface energy by surface treatment (e.g., wet coating, dry coating, e-beam coating, etc.) with fluorine-based polymer compounds (perfluoroalkyl acrylate or PFA, etc.).

However, in this surface treatment method according to the conventional art, there is a limit to reducing the surface energy due to the limitation of the fluorine-based compound material, and for this reason, there is a limitation in preventing contaminants from adhering to surfaces. Referring to Table 1 (water contact angle and oil contact angle in the conventional technology) below, the water contact angle and oil contact angle in the conventional technology are relatively small, because the surface energy cannot be lowered below a certain level. As the surface energy becomes lower, the water contact angle and oil contact angle of the surface become greater, resulting in a reduction in the adhesion of contaminants to the surface.

TABLE 1

| Surface energy | | Water contact angle/ |
|---|---|---|
| (dyn/cm) | Material | oil contact angle |
| 5-10 | PFA(perfluoroalkyl acrylate) | 119°/70° |
| | PFPE (perfluoro polyether) | |
| 70-100 | Glass metal | 30°/5° |

Transition of the surface state is described by the following equations:

$$cos θ = γ \frac{( {γ}_{{S}_{V}} - {γ}_{{S}_{L}} )}{{γ}_{{L}_{V}}} = γ cos θ , \\ γ = 1 + \frac{2 h}{a + b} ( surface roughness coefficient ) , and$$

$$cos θ = f ( 1 + cos θ ) - 1 , f = \frac{a}{a + b}$$

Specifically, the transition from the former Wenzel state (which is an equilibrium state in which contaminants come in complete contact with the surface) to the latter Cassie-Baxter state (in which contaminants float on the surface structure without coming into contact with the surface) is required. In this Cassie-Baxter state, super water-repellent and super oil-repellent properties are realized, and thus contaminants such as water or oil are not adsorbed into the surface structure. The parameters a, b, h and θ in the above equations are as shown in FIGS. 1(A) and 1(B).

### SUMMARY OF THE INVENTION

The present invention is intended to improve the surface treatment method to thereby provide a method for forming a super water-repellent and super oil-repellent surface, in which a surface is treated by lowering the surface energy close to zero (0) so that contaminants can be detached from the surface without being adsorbed on the surface, thereby making the surface state a super water-repellent and super oil-repellent Cassie-Baxter state, and an object manufactured by the method.

The present invention is directed to a method for making the surface state a super water-repellent and super oil-repellent Cassie-Baxter state. If a surface structure is formed according to the method of the present invention, surface roughness (γ) is increased (cos θ_{f}=γ cos θ), and therefore the existing either water-repellent or hydrophilic surface state can be made into either super water-repellent or superhydrophilic.

In the case the surface material is hydrophilic, it is changed to super-hydrophilic because of increase in roughness (on the other hand, a water-repellent state changes to a super water-repellent state). Also since a glass or plastic cover used as a cover for conventional display devices has hydrophilic property, it is possible to accomplish a super water-repellent and super oil-repellent state by changing the surface state to a water-repellent state by means of a fluorine-based compound according to the above way.

Shortly speaking, the fundamental concept of the present invention is to form an anti-fingerprint (AF) surface using nano-patterning. In order to prevent contamination with fingerprints, cosmetic products or the like to thereby realize a high-quality AF function, method of the present invention comprises the steps of: directly patterning by etching a surface of a target, such as a tempered glass surface of devices (e.g., IT devices), a silicon wafer surface, or a polymer surface, to thereby form a surface structure; and providing conformal coating on the surface structure with a fluorine-based compound, to form a super oil-repellent surface and resultantly forming an AF coating.

In the present invention, for the formation of the surface structure of a target, two peculiar etching methods may be used; and for conformal coating on the surface structure, e-beam (electron beam) deposition, iCVD (initiated chemical vapor deposition), HW-CVD (hot wire CVD), ALD (atomic layer deposition) or the like may be used.

The use of iCVD has an advantage over general chemical vapor deposition methods in that modification of the fluorine-based compound does not occur, because a chamber with hot wires having a relatively low temperature (200 to 500° C.) is used (substrate requires no additional heat). In iCVD, a polymer compound in a gaseous state is introduced to a substrate at a vacuum level of 0.1-1 Torr and polymerized using an initiator (thermal initiator or photoinitiator). Examples of the fluorine-based polymer compound include CₙFₘ (e.g., C₆-C₁₂) fluorine-based compounds (homopolymers or mixtures) such as perfluorodecyl acrylate, pentafluorophenyl acrylate, or pentafluorobenzyl acrylate. As the initiator, a peroxide-based initiator is used.

More specifically, the method for forming the super water-repellent and super oil-repellent surface according to the present invention comprises the steps of: etching the surface of a target on which the super water-repellent and super oil-repellent surface is to be formed, thereby forming a surface structure including continuous concave parts ( [symbol] ) and concave parts ( [symbol] ); and conformally coating a fluorine-based material on the surface structure, formed on the surface of the target by etching, in such a manner that all the surfaces of the concave parts and all the surfaces of the convex parts are coated at a uniform thickness.

Where the target is one of glass, tempered glass, silicon wafer, and polymer, the step of forming the surface structure comprises the steps of: forming a metal layer on the target surface; annealing the metal layer to form metal mask patterns; performing reactive ion etching (RIE) through the metal mask pattern to etch the target; and removing the metal mask pattern from the etched target surface. On the other hand, where the target is one of glass (excluding tempered glass), silicon wafer, polymer, and a mold for polymer replication, the step of forming the surface structure comprises the steps of: forming photoresist on the target surface; exposing the photoresist to light using a patterned physical mask to form a patterned photomask; performing reactive ion etching (RIE) through the photomask to etch the target; and removing the photomask.

In addition, the step of conformally coating the fluorine-based material on the surface structure of the target at a uniform thickness comprises: performing e-beam deposition with a fluorine-based material in a state in which the target is inclined such that a plane including the surface of the target is inclined at an angle greater than 0° but less than 90° with respect to the direction of movement of e-beam electrons, and, at the same time, rotating the target centering around an axis perpendicular to the surface of the target.

Here, the fluorine-based material may include perfluoroalkyl acrylate (PFA) or methacrylate, which is the fluorine-based polymer H₂C═CHCO₂(CH₂)ₓC_{y}F_{z}, or perfluoropolyether (PFPE). In addition, the method of the present invention may further comprise: before performing the e-beam deposition, coating the surface structure of the target with SiO₂. Also it may further comprise: generating plasma in the process chamber.

As an alternative, the step of conformally coating the fluorine-based material on the surface structure of the target at a uniform thickness may also be performed by performing iCVD deposition of the fluorine-based material on the surface structure of the target.

In this case, the fluorine-based material may include perfluoroalkyl acrylate (PFA) or methacrylate, which is the fluorine-based polymer H₂C═CHCO₂(CH₂)ₓC_{y}F_{z}. In addition, in order to enhance the strength of a layer formed by the iCVD deposition, a crosslinker may be added to the fluorine-based material.

In addition, the method of the present invention may further comprise: before performing the iCVD deposition, reacting the target with 2 wt % of surface treatment agent (selected from among SAM from Sigma-Aldrich, alkoxy group, halogen group, vinyl group, and acryl group) in toluene. Also it may further comprise: before performing the iCVD deposition, coating the surface structure of the target with SiO₂. Additionally, it may further comprise: generating plasma in the process chamber.

The iCVD deposition in the present invention is performed in a manner that a target is inclined such that a plane including the target surface forms an angle greater than 0° but less than 90° with respect to the direction of deposition, while the target is rotated with respect to an axis perpendicular to the surface of the target. By doing so, more uniform conformal coating is possible.

According to another aspect of the invention, there is provided an object, such as plastic or glass enclosures, mobile phones, LCD display, etc., having a super water-repellent and super oil-repellent surface formed thereon, wherein a surface structure including continuous concave parts and convex parts is formed on the surface of the target, and a fluorine-based material is coated on all the surfaces of the concave parts and all the surfaces of the convex parts on the surface structure at a uniform thickness.

The construction and effects of the present invention as described above will be more clearly understood from the following description of the present invention with reference to the accompanying drawings.

### BRIEF DESCRIPTION OF THE DRAWINGS

FIG. 1(A) and FIG. 1(B) depict schematic surface structure diagrams illustrating the Wenzel state and the Cassie-Baxter state, respectively.

FIGS. 2(A) to 2(E) illustrate a first embodiment for formation of a surface structure.

FIG. 3(A) and FIG. 3(B) show photographs of metal mask patterns (30).

FIG. 4(A) and FIG. 4(B) show photographs of a final surface structure after etching.

FIGS. 5(A) to 5(E) illustrate a second embodiment for formation of a surface structure.

FIG. 6 is a view showing formed nano-micro photomask patterns.

FIG. 7 shows a photograph of a final surface structure after etching.

FIGS. 8(A) and 8(B) are conceptual view of conventional e-beam deposition.

FIGS. 9(A) and 9(B) are conceptual view of e-beam deposition according to the present invention.

FIG. 10(A) and FIG. 10(B) show photographs comparing fingerprint contamination.

FIG. 11 shows a conformal coating process according to a first embodiment (e-beam deposition).

FIG. 12 shows a conformal coating process according to a second embodiment (iCVD).

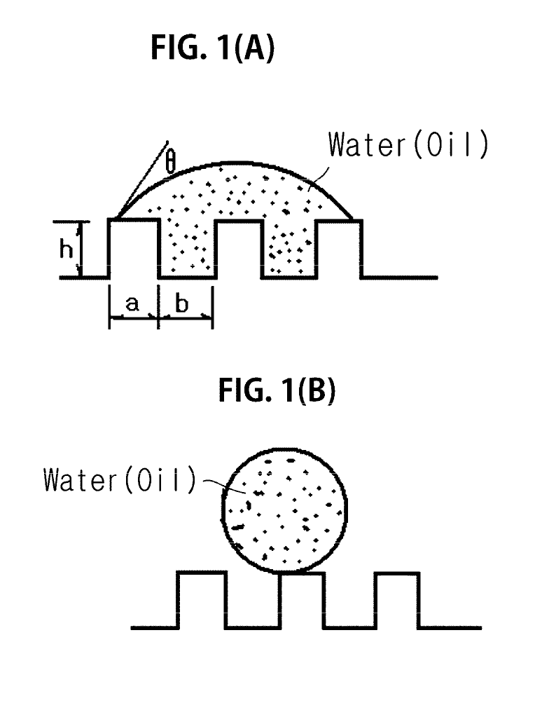

### DETAILED DESCRIPTION OF THE INVENTION

A method for forming a super water-repellent and super oil-repellent surface according to an embodiment of the present invention comprises the steps of: (1) etching the surface of a target on which the super water-repellent and super oil-repellent surface is to be formed, thereby forming a surface structure including continuous concave parts and convex parts; and (2) conformally coating a fluorine-based material on the surface structure formed on the target surface by etching, in such a manner that all the surfaces of the concave parts and all the surfaces of the convex parts are coated at a uniform thickness.

Step (1) forming surface structure on the target (all kinds of glass, a Si wafer, a polymer, a mold for polymer replication, etc.) may be performed by using a method selected from among the two methods described below.

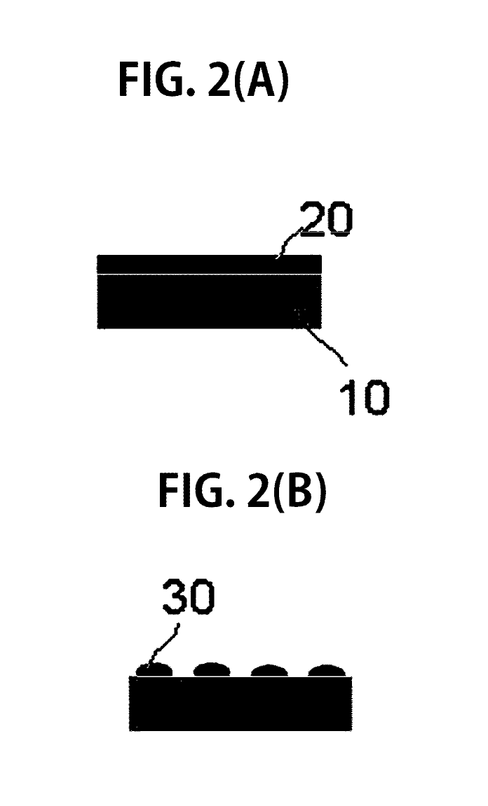

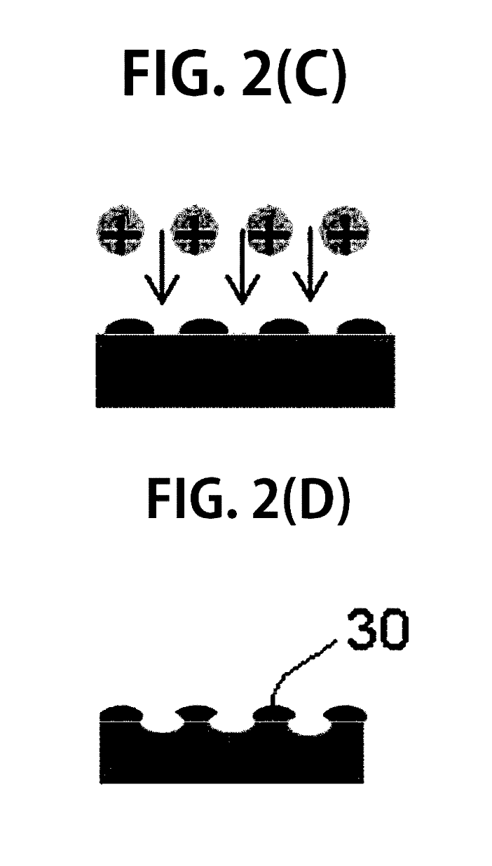

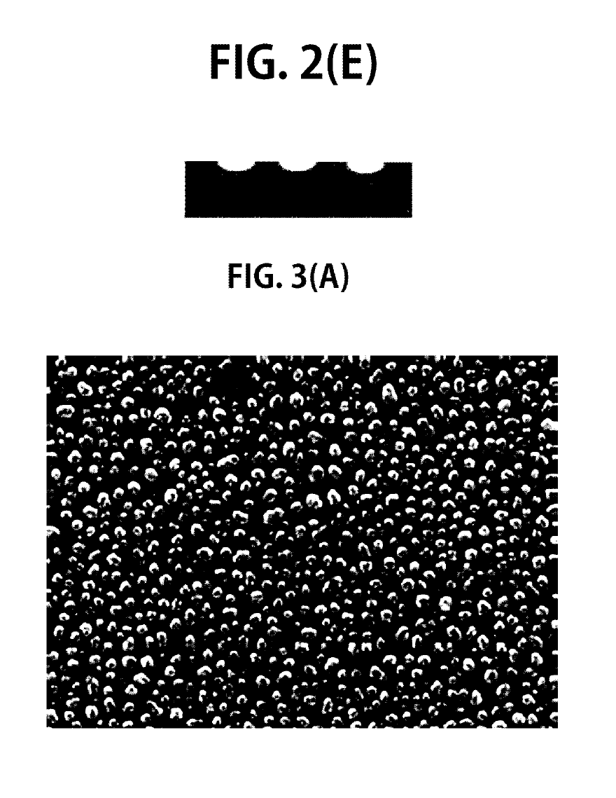

First, where the target is glass, tempered glass, a silicon wafer or a polymer, the surface structure is formed using the method shown as in FIGS. 2(A) to 2(E). This method may be applied to all targets. Particularly, where the target is tempered glass, only this method can be used.

As shown in FIG. 2(A), on a target 10 on which a structure is to be formed, a metal layer 20 made of Ag, Bi, Pt, Cu, Cr or the like is deposited to a thickness ranging from several nm to several hundred nm. The deposition may be performed by means of sputtering.

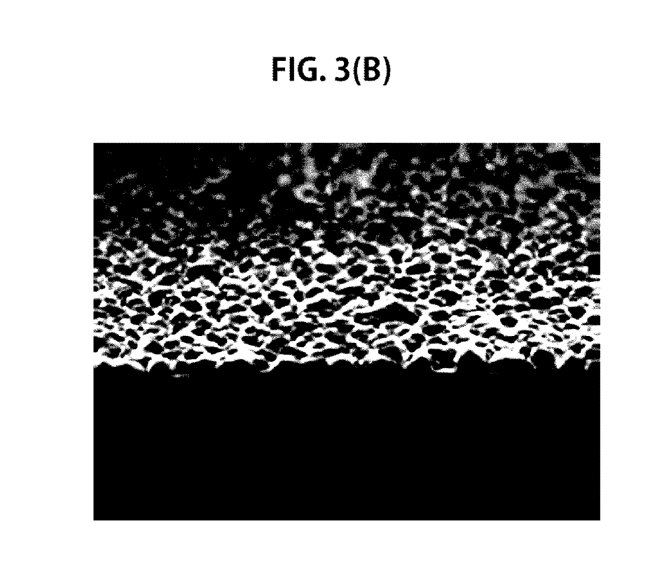

As shown in FIG. 2(B), on the metal layer 20, mask patterns 30 having a size of several ten nm to several hundred nm are formed at intervals several ten nm to several hundred nm (several μm is also possible) by annealing (during several minutes to several ten minutes, preferably during 3 to 6 minutes) using a furnace and an RTA system at a high temperature (200° C. to 400° C.). FIGS. 3(A) and 3(B) show photographs of the metal mask patterns 30 formed as described above. FIG. 3(A) is a top view of the mask patterns 30, and FIG. 3(B) is a cross-sectional view of the mask patterns 30.

As shown in FIG. 2(C), the target is etched by reactive ion etching (RIE) using the formed metal mask 30. In the etching, CHF₃ gas, CF₄ gas or a combination thereof is used at a flow rate of several tens of sccm, preferably 10-30 sccm. The vacuum level of the RIE system ranges from several mTorr to 10⁻³ Torr. The etching time ranges from several minutes to several tens of minutes, preferably from 3 to 6 minutes.

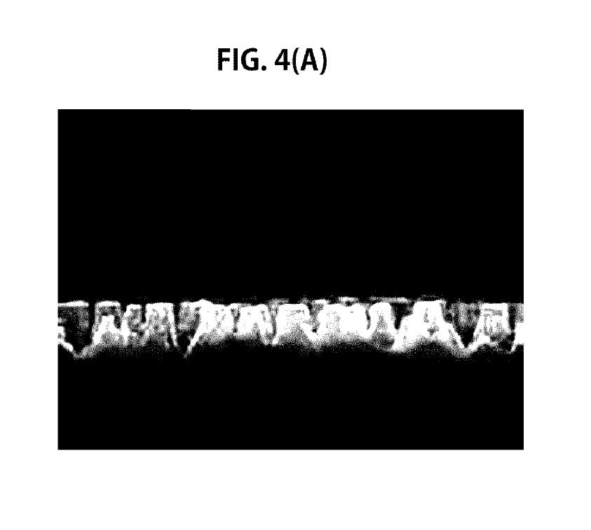

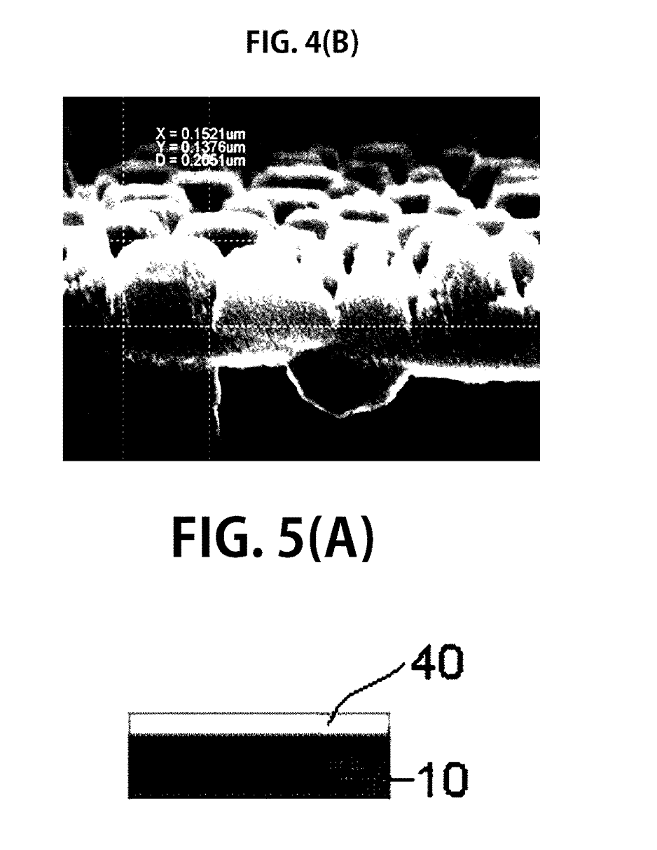

FIG. 2(D) shows the etched target. The patterns formed as described above most preferably have the shape as shown in the figure in view of durability. Preferably, the ratio of the depth of the patterns to the distance between the patterns is 1:3 to 1:1 or is adjusted according to super oil-repellent pattern conditions corresponding to the Cassie-Baxter state. FIG. 4(A) is a cross-sectional view of nano to micro patterns formed on the target by etching, and FIG. 4(B) is a perspective view of the top of the patterns.

As shown in FIG. 2(E), the metal mask 30 attached to the surface of the target is removed using hydrochloric acid or nitric acid. The final surface structure after etching is as shown in FIGS. 4(A) and 4(B). FIG. 4(A) is a cross-sectional view of the final surface structure, and FIG. 4(B) is a perspective view of the top of the final surface structure.

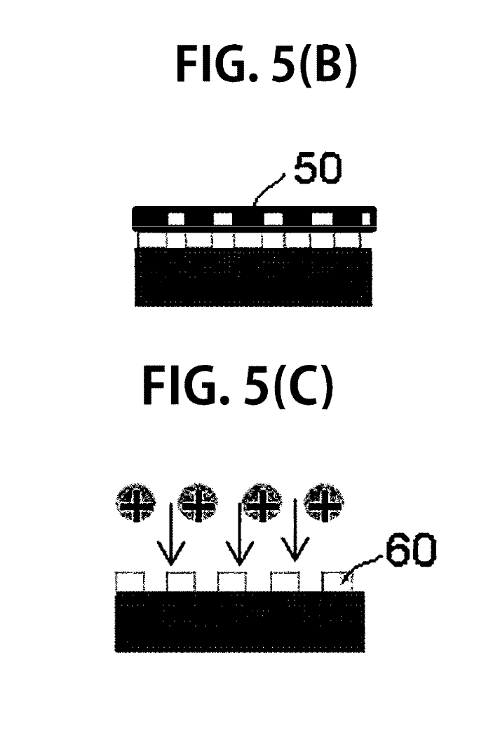

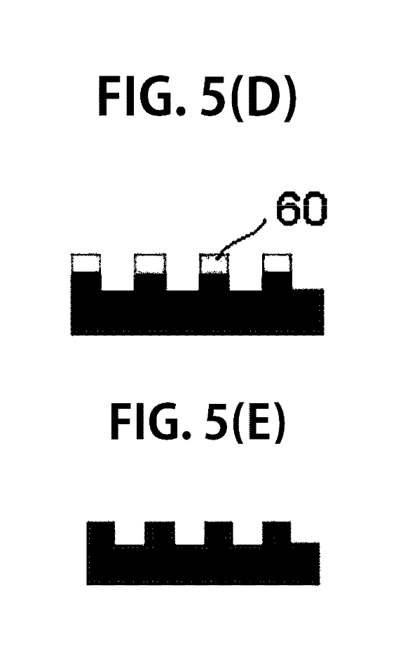

Second, where the target is glass, a silicon wafer, a polymer, a mold for polymer replication, or the like, the surface structure is formed using the method as shown in FIGS. 5(A) to 5(E). This method cannot be applied to a target made of tempered glass.

As shown in FIG. 5(A), on a target 10 on which a surface structure is to be formed, a photoresist 40 is formed, using a deep RIE process, to a thickness of several nm to several μm by spin coating and heat treatment.

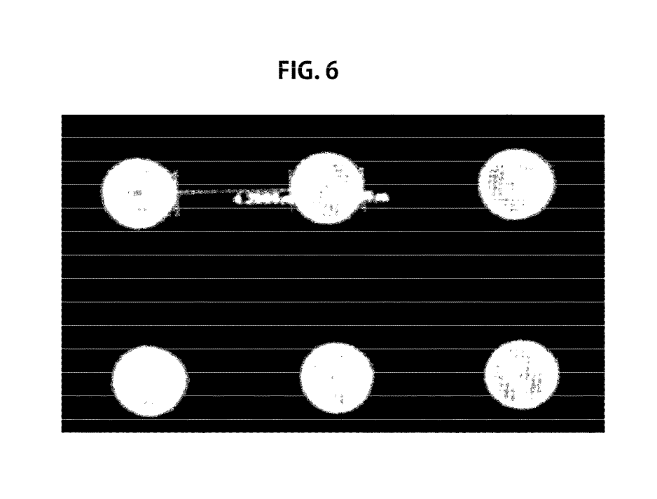

As shown in FIG. 5(B), using a metal mask 50 (made of Cr or the like) in which square or hexagonal holes are arranged at intervals corresponding to super oil-repellent pattern conditions, exposure to UV light is performed to form a photomask. Herein, the target 10 is etched by plasma gas (SF₆) to form mask patterns, and gas such as C₄F₈ or C₄F₆ is deposited on the patterns or a passivation process is performed, thereby forming final photomask patterns 60 having a high aspect ratio. The formed nano to micro photomask patterns are as shown in FIG. 6. The distance between holes in these patterns is determined according to super oil-repellent pattern conditions.

As shown in FIG. 5(C), the target is etched by reactive ion etching (RIE) through the formed photomask patterns 60. As the etching gas above, CHF₃ gas, CF₄ gas or a combination thereof is used at a flow rate of several tens of sccm, preferably 10-30 sccm. The vacuum level of the RIE system ranges from several mTorr to 10⁻³ Torr. The etching time ranges from several minutes to several tens of minutes, preferably from 3 to 6 minutes.

FIG. 5(D) shows the etched surface of the target 10.

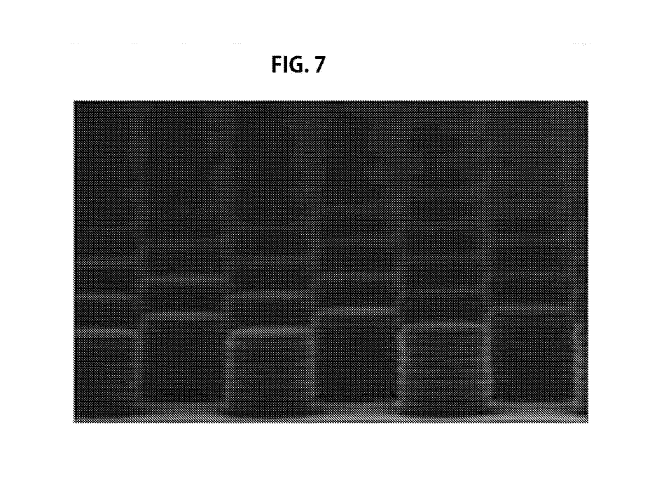

As shown in FIG. 5(E), the photomask patterns 60 attached to the etched target surface is removed using hydrochloric acid or nitric acid. The final surface structure after etching is as shown in FIG. 7.

Hereinafter, step (2) conformal coating of the fluorine-based material on the surface structure formed on the surface of the target will be described.

The surface energy of the target 10 can be minimized by depositing (coating) the fluorine-based material on the surface structure formed on the target 10 as described above. However, if deposition is performed using a conventional deposition method (e-beam deposition, thermal deposition, spray deposition, etc.), a super oil-repellent state corresponding to a water contact angle of 140° or more can be obtained, but oil-repellent properties against fats and oils (fatty acids, oleic acids, etc.), which account for the majority of fingerprint components, and the oily components of cosmetic products (water and 70% oily components such as oils and lipids), will not be easily improved. For transition from such oil-repellent properties to super oil-repellent properties, the pattern conditions as described above should be setup, and a fluorine-based compound or the like should be able to be conformally coated on the surfaces of all the pattern surfaces of the surface structure. The present invention proposes two conformal coating methods for the step of conformal coating of a fluorine-based compound or the like.

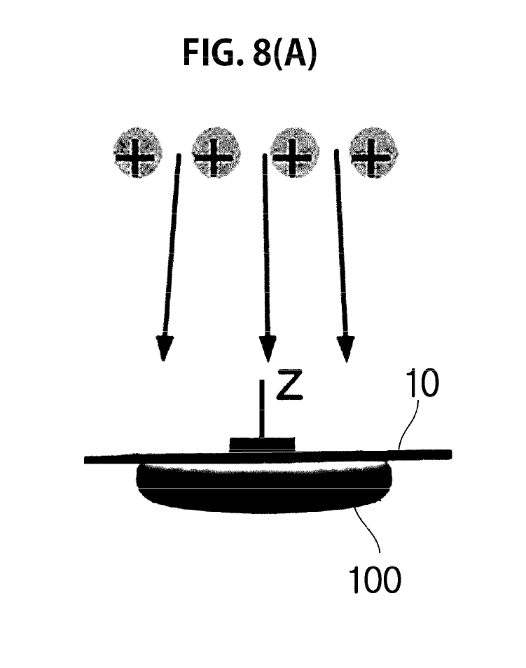

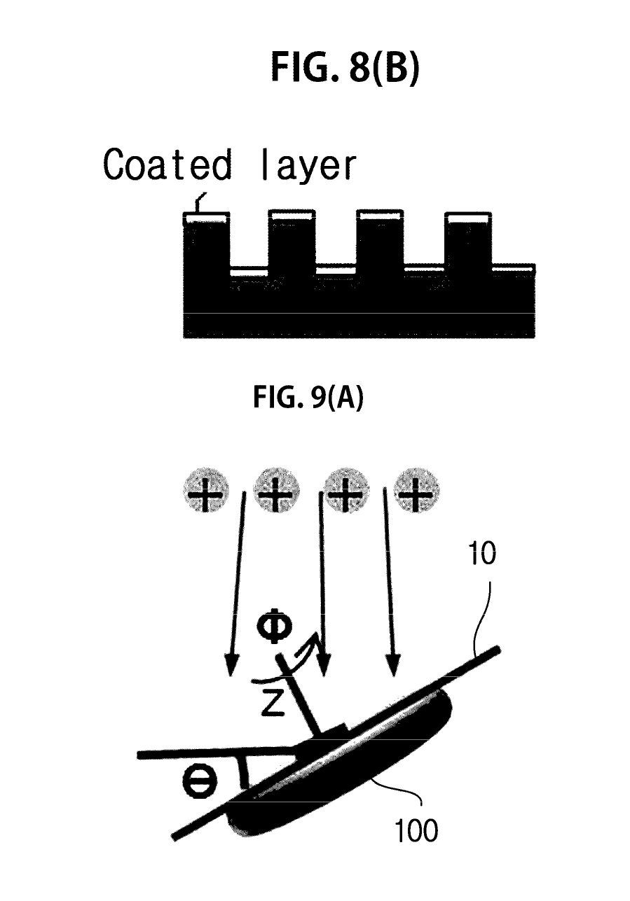

First refer to FIGS. 8(A) and 8(B). In the case of e-beam deposition, when a fluorine-based compound is deposited on the surface structure patterns of the target 10 by an electron beam from an ion gun, it is deposited mainly on the top surfaces of the formed patterns and on the bottom surfaces between the patterns. Due to this shortcoming, it is impossible for a conventional e-beam method to conformally deposit the fluorine-based compound on the patterns.

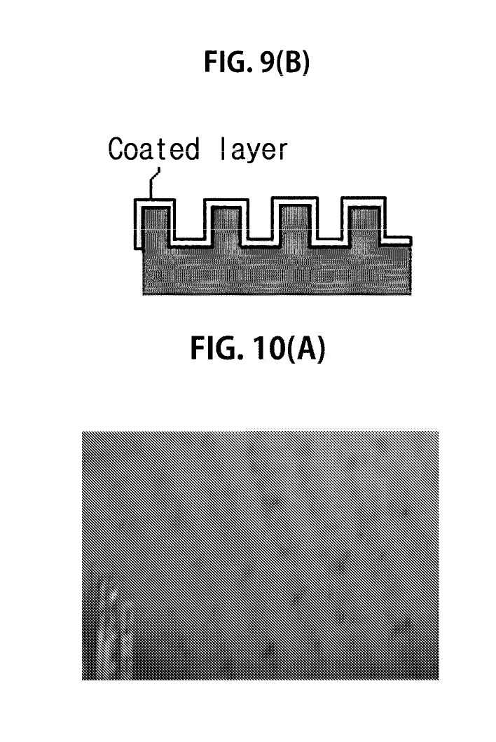

To overcome this shortcoming, as shown in FIGS. 9(A) and 9(B), a stage 100 in an e-beam deposition system, on which the target 100 is mounted, is inclined at an angle of θ with respect to a plane perpendicular to the direction of electrons movement, that is, a plane including the surface of the target 10, and the stage 100 is rotated with respect to an axis Z perpendicular to the surface of the target 10 so that the lateral portions of the patterns can be also conformally coated. Herein, the inclined angle θ is greater than 0° but less than 90°, and the stage 100 is rotated with respect to the Z axis at a speed of a few RPM during the deposition process.

As a result, as shown in Table 2 below, an increase in the oil contact angle (hexadecane) compared to the conventional e-beam deposition method can be obtained. This increased contact angle indicates that super oil-repellent properties can be realized by adjusting the surface structure patterns.

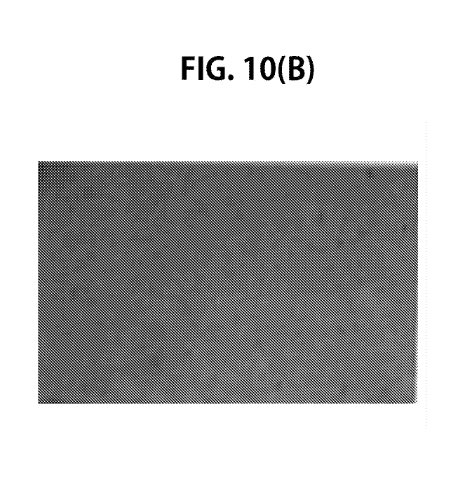

FIGS. 10(A) and 10(B) show the results of fingerprint contamination tests for the surfaces formed as described above. Specifically, FIG. 10(A) shows fingerprint contamination of the coating surface formed by the conventional e-beam deposition method. FIG. 10(B) shows fingerprint contamination of the coating surface formed by the e-beam deposition method of the present invention. It can be seen that little or no fingerprint contamination of the surface shown in FIG. 10(B) occurred, unlike the surface shown in FIG. 10(A).

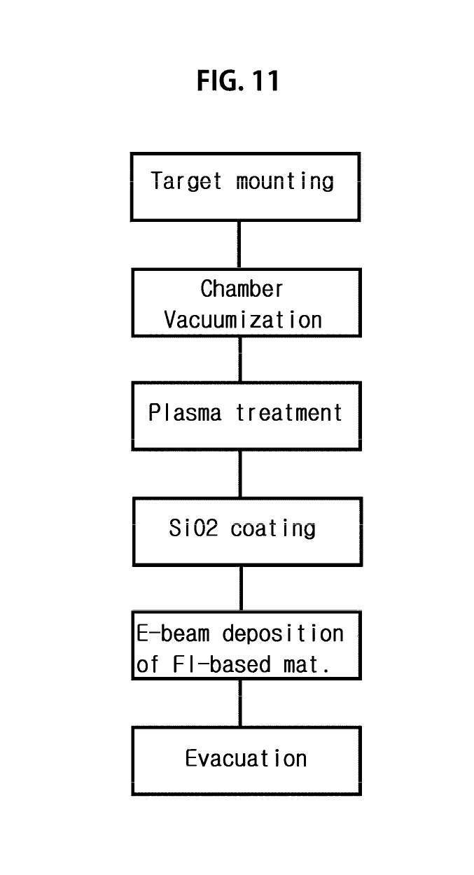

A process for carrying out this method of the present invention will now be briefly described with reference to FIG. 11. First, a target is mounted on a stage built in a chamber, and the pressure of the chamber is reduced to a vacuum level (the vacuum level of the e-beam chamber is adjusted to 10⁻⁴ to 10⁻⁵ Torr). Next, in an optional process for removing impurities, plasma such as Ar is introduced into the chamber by an ion gun at 80° C. for several minutes, preferably 5 minutes. Next, SiO₂ is coated on the surface of the target to a thickness of several tens of Å to 50 Å, and then a fluorine-based compound (PFA- or PFPE-based) is deposited to a thickness of several hundreds of Å to 300 Å for several minutes, preferably 1 minute and 30 seconds. Herein, why SiO₂ coating is first performed is to increase the adhesive strength of the fluorine-based compound to the surface structure of the target to thereby enhance durability. For the fluorine-based compound, the fluorine-based polymer H₂C═CHCO₂(CH₂)ₓC_{y}F_{z} (perfluoroalkyl acrylate (PFA) or methacrylate) or perfluoropolyether (PFPE) may be used.

The second possible conformal coating method according to the present invention is a process of depositing the fluorine-based compound by iCVD.

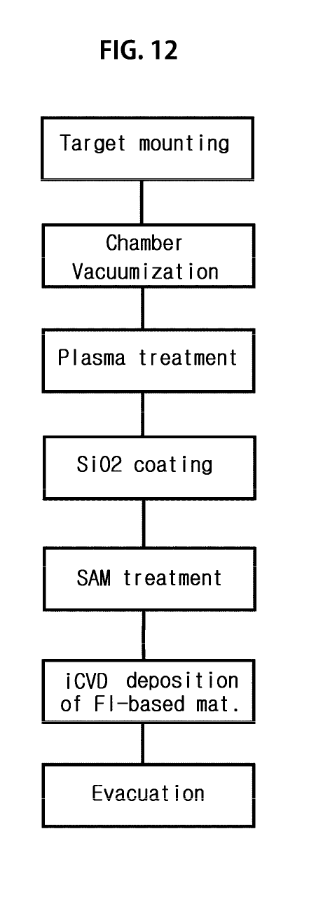

This method is performed by the process shown in FIG. 12, which is fundamentally similar to the process shown in FIG. 11. First, like the process shown in FIG. 11, a target is mounted to a stage in a chamber, and the pressure of the chamber is reduced to a vacuum level. Next, in an optional process for removing impurities, the target in the chamber is plasma-treated with Ar gas or the like by an ion gun. Then, the surface of the target is coated with SiO₂. Herein, coating with SiO₂ is performed in order to increase the adhesive strength of the fluorine-based compound to thereby enhance durability. Next, self-assembled monolayer (e.g., SAM) treatment is optionally performed in order to improve the performance of the process. For SAM treatment, the target is reacted with 2 wt % of a surface treatment agent (one selected from among SAM from Sigma-Aldrich, an alkoxy group, a halogen group, a vinyl group, and an acryl group) in toluene at 90° C. for 2 hours. Herein, the alkoxy group may be one or more of epoxy, propoxy, hexyloxy, heptyloxy and octyloxy, and the halogen group means elements of a group 17 such as F, Cl, Br or I. The vinyl group and the acryl group may be one or more C₁˜C₁₂ alkyl groups such as a methyl group or an ethyl group. After the SAM treatment is performed (or immediately after SiO₂ coating is performed), iCVD deposition of a fluorine-based compound is performed. For the fluorine-based compound, the fluorine-based polymer H₂C═CHCO₂(CH₂)ₓC_{y}F_{z} (e.g., perfluoroalkyl acrylate (PFA) or methacrylate) may be used. In order to enhance the strength of the coating layer, a cross-linker (e.g., diacylate-based hydrocarbon) may be added to the fluorine-based polymer. Herein, the ratio of the fluorine-based polymer to the cross-linker is 1:0.5/0.2/1. The vacuum level of the chamber is adjusted to 10⁻⁴ to 10⁻³ Torr, and the deposition time is 50-60 sec. or 120 sec. After the deposition process, end-capping is performed for 50 seconds. Herein, the deposition thickness is 15 nm/20 nm/55 nm.

The effect of the iCVD method on the increase in the contact angle is as shown in Table 1 above.

Meanwhile, in order to maximize the effect of the iCVD deposition method of the present invention, like the inclined e-beam deposition method shown in FIG. 9(A), a stage 100 in an e-beam deposition system, on which the target 10 is mounted, is inclined at an angle of θ with respect to a plane perpendicular to the direction of movement of electrons, that is, a plane including the surface of the target 10, and the stage 100 is rotated with respect to an axis Z perpendicular to the surface of the target 10 so that the lateral portions of the patterns can also be conformally coated. Herein, the inclined angle θ is greater than 0° but less than 90°, and the stage is rotated with respect to the Z axis at a speed of a few RPM during the deposition process.

With the explosive diffusion of mobile devices such as smartphones and tablet PCs worldwide, the user demand for the high functionality of cover windows of mobile devices against contamination with fingerprints or cosmetic products is increasing. Currently, the major shortcoming of mobile devices such as smartphones and tablet PCs in the point of view of consumers is the contamination of cover windows by fingerprints or cosmetic products, and it is required to alleviate contamination of such cover windows.

The present invention is directed to a technology capable of dramatically solving problems associated with contamination of such cover windows. When the technology of the present invention is applied, existing cover windows (made mostly of tempered glass) can maintain excellent surface hardness characteristics while the surface properties (antifouling properties) of such cover windows are not deteriorated, even when they are used for a long period of time.

According to the present invention, a technology capable of solving the shortcomings of cover windows of mobile devices can be preoccupied, and thus a leading technology for the key parts of mobile devices in the world can be ensured, resulting in an increase in technological competitiveness.

In addition, if the glass manufacturing technology that uses this AF function is applied to the cover glass of solar cell modules, it can result in an increase in the power generation throughput of the solar cell modules. The present invention can also be applied to surface contamination prevention technology. The surface contamination prevention technology that is obtained by the technology of the present invention can also be applied to various household electrical appliances (enclosure surfaces of refrigerators or air conditioners), and can increase the satisfaction of the consumers of household electrical appliances and the product competitiveness of companies that manufacture them.

As additional advantages, the present invention can increase technological competitiveness, thereby increasing the product competitiveness of companies that manufacture window covers for smart mobile devices. In addition, the technology of the present invention can enhance the competitiveness of the domestic smart mobile device industry, resulting in an increase in the sale of related products. In social terms, when the product resulting from the present invention is applied to mobile devices, it can increase the satisfaction of global consumers of the products by minimizing contamination with fingerprints, sweat, cosmetic products or the like.

What is claimed is:

1. A method for forming a super water-repellent and super oil-repellent surface, comprising the steps of:
etching a surface of a target on which the super water-repellent and super oil-repellent surface is to be formed, thereby forming a surface structure including continuous concave parts and convex parts; and
conformally coating a fluorine-based material on the surface structure, formed on the surface of the target by etching, in such a manner that all surfaces of the concave parts and all surfaces of the convex parts are coated at a uniform thickness.

2. The method of claim 1, wherein the target is one of glass, tempered glass, silicon wafers, and polymers; and
the step of forming the surface structure comprises the steps of:
forming a metal layer on the surface of the target;
annealing the metal layer to form metal mask patterns;
performing reactive ion etching (RIE) through the metal mask patterns to etch the target; and
removing the metal mask patterns from the surface of the etched target.

3. The method of claim 1, wherein the target is one of glass (excluding tempered glass), silicon wafers, polymers, and molds for polymer replication; and
the step of forming the surface structure comprises the steps of:
forming photoresist on the surface of the target;
exposing the photoresist to light using a patterned physical mask, and then forming a patterned photomask;
performing reactive ion etching (RIE) through the photomask to etch the target; and
removing the photomask.

4. The method of claim 1, wherein the step of conformally coating the fluorine-based material on the surface structure of the target at a uniform thickness comprises:
performing e-beam deposition with the fluorine-based material in a manner that the target is inclined such that a plane including the surface of the target is inclined at an angle greater than 0° but less than 90° with respect to the direction of movement of e-beam electrons, and, at the same time, rotating the target with respect to an axis perpendicular to the surface of the target.

5. The method of claim 4, wherein the fluorine-based material comprises:
one selected among perfluoroalkyl acrylate (PFA) and methacrylate, which are the fluorine-based polymer H₂C═CHCO₂ (CH₂)ₓC_{y}F_{z}.

6. The method of claim 4, further comprising:
coating, before performing the e-beam deposition, SiO₂ on the surface structure of the target.

7. The method of claim 4, further comprising:
generating plasma in a process chamber.

8. The method of claim 1, wherein the step of conformally coating the fluorine-based material on the surface structure of the target at a uniform thickness comprises:
performing iCVD deposition of the fluorine-based material on the surface structure of the target.

9. The method of claim 8, wherein the fluorine-based material comprises:
one selected among sperfluoroalkyl acrylate (PFA), methacrylate, which are the fluorine-based polymer H₂C═CHCO₂(CH₂)xCyFz, and perfluoropolyether (PFPE).

10. The method of claim 9, wherein a crosslinker is added to the fluorine-based material in order to enhance strength of a layer formed by the iCVD deposition.

11. The method of claim 8, further comprising:
reacting, before performing the iCVD deposition, the target with 2 wt % of a surface treatment agent (one selected among SAM from Sigma-Aldrich, an alkoxy group, a halogen group, a vinyl group and an acryl group) in toluene.

12. The method of claim 8, further comprising:
coating, before performing the iCVD deposition, SiO₂ on the surface structure of the target.

13. The method of claim 8, further comprising:
generating plasma in a process chamber.

14. The method of claim 8, wherein the iCVD deposition is performed in a manner that the target is inclined such that a plane including the surface of the target is inclined at an angle greater than 0° but less than 90° with respect to the direction of deposition, while the target is rotated with respect to an axis perpendicular to the surface of the target.

15. An object having a super water-repellent and super oil-repellent surface formed thereon, the object comprising:
a surface structure including concave parts and convex parts continuously formed on a surface of the object; and
a fluorine-based material coated on all surfaces of the concave parts and all surfaces of the convex parts on the surface structure at a uniform thickness.
